(19) United States
(12) Patent Application Publication
(10) Pub. No.: US 2024/0128093 A1
(43) Pub. Date: Apr. 18, 2024

(54) MANUFACTURING METHOD OF ELECTRONIC DEVICE

(71) Applicant: ASUSTeK COMPUTER INC., Taipei City (TW)

(72) Inventors: Xu Wang, Taipei City (TW); Chih-Kuan Liu, Taipei City (TW)

(73) Assignee: ASUSTeK COMPUTER INC., Taipei City (TW)

(21) Appl. No.: 18/073,572

(22) Filed: Dec. 2, 2022

(30) Foreign Application Priority Data
Oct. 14, 2022 (CN) 202211258772.6

(51) Int. Cl. H01L 21/56; H05K 3/30

(52) U.S. Cl. CPC H01L 21/56; H05K 3/30; H01L 23/3736; H05K 2203/095

(57) ABSTRACT

A manufacturing method of an electronic device includes that a chip package is mounted on a circuit board. And an exposed surface of the chip package is bombarded with plasma to clean the surface. The manufacturing method of the electronic device of the application can effectively clean the chip package without reducing the reliability of the electronic device.

### CROSS-REFERENCE TO RELATED APPLICATION

This application claims the priority benefit of China application serial no. 202211258772.6, filed on Oct. 14, 2022. The entirety of the above-mentioned patent application is hereby incorporated by reference herein and made a part of this specification.

### BACKGROUND

### Technical Field

The disclosure relates to a manufacturing method of an electronic device.

### Description of Related Art

In recent years, with the increasing development of the technology industry, electronic products such as desktop computers, notebook computers and tablet computers have been widely used in daily life. Electronic devices are equipped with a central processing unit (CPU), graphics processing unit (GPU) or other electronic components, and these electronic components generate heat during operation. A commonly used heat dissipation method is to apply a heat dissipation paste between the heat sink member and the heat-generating component. The heat dissipation paste can fill the gap between the heat sink member and the heat-generating component, and conduct the heat energy of the heat-generating component to the heat sink member to achieve the effect of heat dissipation.

In order to meet users' needs for better heat dissipation, liquid metal is also used to replace heat dissipation paste to improve thermal conductivity. However, if the surface cleanliness of the heat-generating component is not good, the liquid metal droplets will not be well attached to the surface of the heat-generating component due to the excessive surface tension. Therefore, at present, the surface of the heat-generating component will be wiped and cleaned with organic or inorganic, neutral and acid-base solutions such as alcohol, baking soda, dust-free cloth or paper. However, these cleaning products are not easy to control, the cleaning method is complicated, and the residual solution will corrode the heat-generating component.

### SUMMARY

The present invention is directed to a manufacturing method of an electronic device, which can improve the cleaning effect.

According to an embodiment of the present invention, the manufacturing method of the electronic device includes mounting a chip package on a circuit board; and bombarding an exposed surface of the chip package with plasma to clean the surface.

According to an embodiment of the present invention, the manufacturing method of the electronic device further includes dropping a liquid metal on the surface.

According to an embodiment of the present invention, the manufacturing method of the electronic device further includes fixing a heat sink member on the surface, wherein the liquid metal is located between the heat sink member and the surface.

According to an embodiment of the present invention, wherein the material of the surface of the chip package mounted on the circuit board is made of glass.

According to an embodiment of the present invention, wherein the chip package mounted on the circuit board is a graphics processor.

In the manufacturing method of the electronic device according to the embodiment of the present invention, using plasma to bombard and clean the surface of the chip package has a good cleaning effect and reduces damage to the chip package.

### BRIEF DESCRIPTION OF THE DRAWINGS

FIG. 1 to FIG. 5 are flowcharts illustrating a manufacturing method of an electronic device according to an embodiment of the present invention.

FIG. 6 is a partial cross-sectional view of the electronic device after the steps of FIG. 5 are completed.

### DESCRIPTION OF THE EMBODIMENTS

Reference will now be made in detail to exemplary embodiments of the present invention, examples of which are illustrated in the accompanying drawings. Wherever possible, the same reference numerals are used in the drawings and description to refer to the same or like parts.

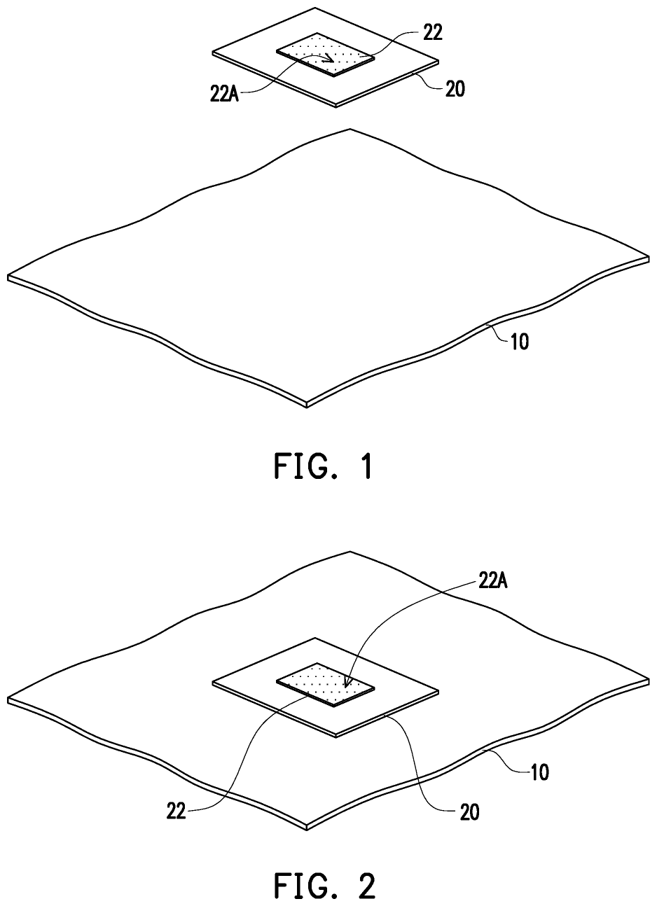

FIG. 1 to FIG. 5 are flowcharts illustrating a manufacturing method of an electronic device according to an embodiment of the present invention. Referring to FIG. 1 and FIG. 2, in the manufacturing method of the electronic device according to the embodiment of the present invention, the chip package 20. is first installed on the circuit board 10. The chip package 20 may be a central processing unit (CPU), a graphics processing unit (GPU) or other electronic components. The chip package 20 has not been cleaned before the chip package 20 is mounted on the circuit board 10 and after the chip package 20 is mounted on the circuit board 10.

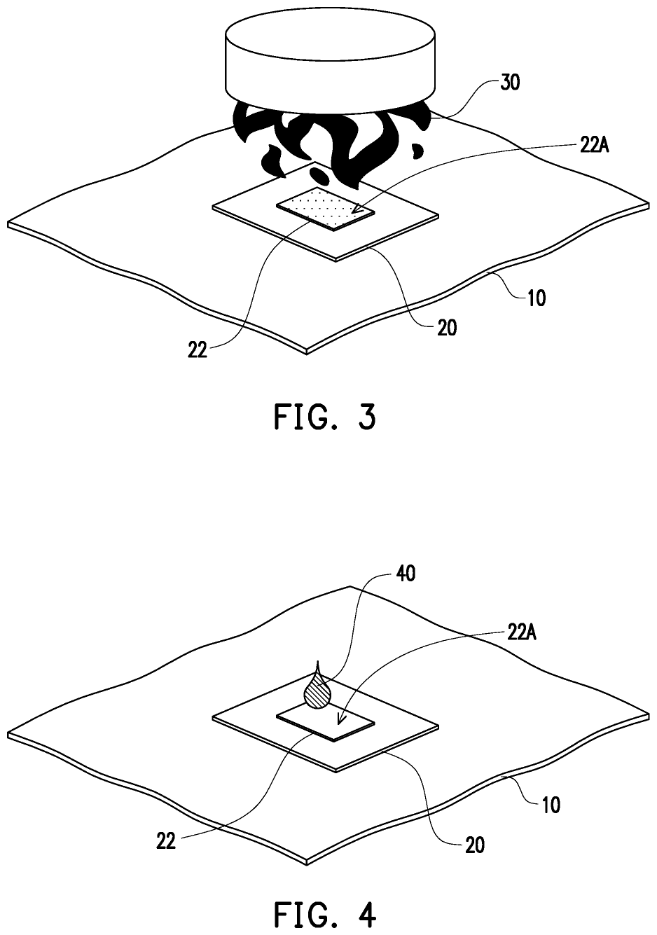

Next, referring to FIG. 3, the exposed surface 22A of the chip package 20 is bombarded with plasma 30 to clean the surface 22A. In an embodiment, a special plasma cleaning machine can be used, and it is only necessary to place the circuit board 10 with the chip package 20 to be cleaned under the plasma nozzle of the machine. The plasma ejected from the nozzle will break the organic bonds of the dirt on the surface 22A, and then decompose the dirt and react and clean it by the high-energy oxygen species in the plasma, while the generated water and carbon dioxide are discharged. In this way, the surface 22A of chip package 20 can be returned to an uncontaminated clean state.

Control costs can be saved by not using cleaning supplies such as alcohol, baking soda solution, dust-free cloth or paper. Because the plasma 30 bombardment is carried out automatically by the machine, there is no need to worry that manual cleaning may use too many cleaning products and cause residues, and it will not use too little cleaning products and cause poor cleaning results. Based on this, it can be avoided that the residue of cleaning products will corrode the chip package 20 or cause a short circuit, and other components on the circuit board 10 will be damaged due to improper overflow control. In addition, problems such as collision of components on the circuit board 10 with the chip package 20 during a wiping process and additional physical damage such as electrostatic breakdown can be avoided.

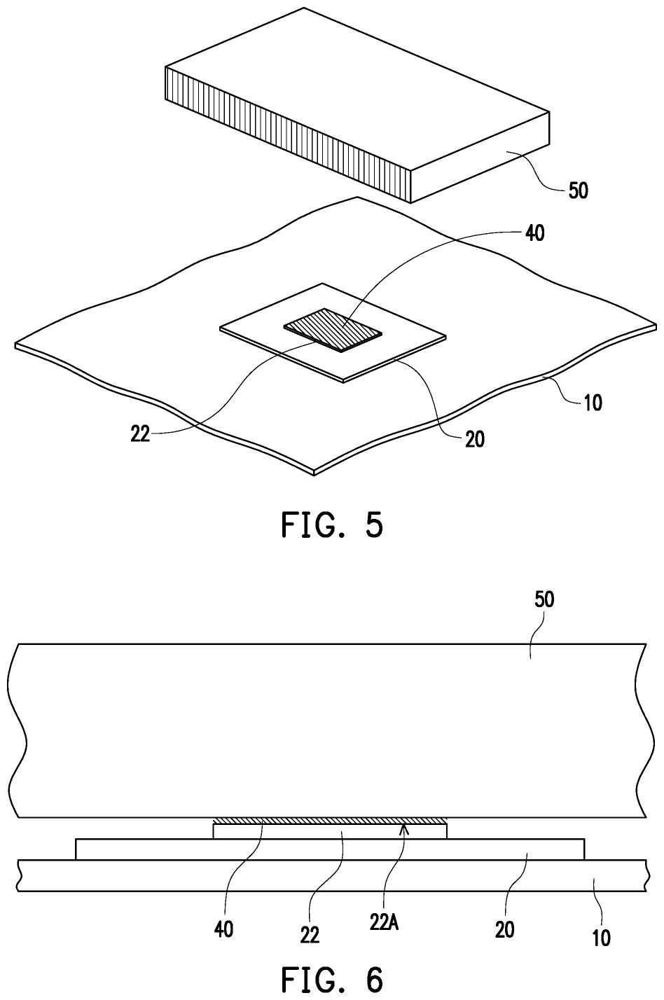

Next, referring to FIG. 4 and FIG. 5, after performing the cleaning step using plasma as shown in FIG. 3, a liquid metal 40 can be dripped onto the surface 22A of the chip package 20. For example, the chip package 20 has a protruding chip 22, and the surface 22A is the surface 22A of chip 22. The chip 22 is the main heat-generating part, so drop the liquid metal 40 on the surface 22A of the chip 22. Since the surface 22A has been cleaned by plasma, a good wetting effect can be produced between the liquid metal 40 and the surface 22A. That is to say, the liquid metal 40 can be evenly distributed on the surface 22A, and the liquid metal 40 will not maintain the state of droplets on the surface 22A due to the cohesive force of the liquid metal 40, resulting in part of the surface 22A not being covered by the liquid metal 40. In the embodiment, the surface 22A of the chip 22 is a low-roughness surface, and its material may be glass or other crystalline materials.

FIG. 6 is a partial cross-sectional view of the electronic device after the steps of FIG. 5 are completed. Next, referring to FIG. 5 and FIG. 6, after performing the step of dripping liquid metal 40 on the surface 22A of the chip package 20 as shown in FIG. 3, a heat sink member 50 can be fixed on the surface 22A. The liquid metal 40 is located between the heat sink member 50 and the surface 22A. Since the appearance of the liquid metal 40 can change with the environment, even if the surface of the surface 22A or the heat sink member 50 is uneven, the liquid metal 40 can still completely fill the space between the heat sink member 50 and the surface 22A, so as to avoid the existence of air and hinder the heat conduction. In this way, the heat energy of the chip package 20 can be effectively conducted to the heat sink member 50 to achieve the effect of heat dissipation and ensure the continuous and efficient operation of the chip package 20. It should be noted that, FIG. 4 to FIG. 6 are only used for schematic description of the principle, so the related structural components such as flow blocking and overflow prevention for liquid metal are not shown.

In the manufacturing method of the electronic device according to the embodiment of the present invention, the surface of the chip package that has been installed on the circuit board is cleaned by bombarding the surface with plasma. It has a good cleaning effect, and can also improve the phenomenon of damage to the chip package caused by residual cleaning supplies in the prior art. In addition, the surface of the cleaned chip package can also be well combined with liquid metal, thereby improving the heat dissipation efficiency.

Finally, it should be noted that the above embodiments are only used to illustrate the technical scheme of the present invention, but not to limit it. Although the present invention has been described in detail with reference to the foregoing embodiments, those of ordinary skill in the art should understand that the technical solutions described in the foregoing embodiments can still be modified, or some or all of the technical features thereof can be equivalently replaced. However, these modifications or substitutions do not make the essence of the corresponding technical solutions deviate from the scope of the technical solutions of the embodiments of the present invention.

What is claimed is:

1. A manufacturing method of an electronic device, comprising:
mounting a chip package on a circuit board; and
bombarding an exposed surface of the chip package with plasma to clean the surface.

2. The manufacturing method of the electronic device according to claim 1, further comprises dropping a liquid metal on the surface.

3. The manufacturing method of the electronic device according to claim 2, further comprises fixing a heat sink member on the surface, wherein the liquid metal is located between the heat sink member and the surface.

4. The manufacturing method of the electronic device according to claim 1, wherein the material of the surface of the chip package mounted on the circuit board is made of glass.

5. The manufacturing method of the electronic device according to claim 1, wherein the chip package mounted on the circuit board is a graphics processor.
